(19) United States
(12) Patent Application Publication
(10) Pub. No.: US 2006/0100108 A1
(43) Pub. Date: May 11, 2006

(54) Superconducting carbon 12 atomic strings and methods of manufacture of cables containing parallel strings

(76) Inventor: Robert W. Beckwith, Clearwater, FL (US)

Correspondence Address: Leo J. Aubel, 111 Rivershire Lane, Lincolnshire, IL, 60069, US

(21) Appl. No.: 11/073,156

(22) Filed: Mar. 5, 2005

Related U.S. Application Data
(63) Continuation-in-part of application No. 10/983,380, filed on Nov. 8, 2004.

(51) Int. Cl. H01L 39/24

(52) U.S. Cl. 505/100

(57) ABSTRACT

A string of super-dense carbon atoms forms a superconductor unaffected by temperature changes over a wide range. Using molecular beam epitaxy technology, a number of such carbon atomic strings are connected in parallel and encased in a plastic which forms nanotubes around each string having a negatively charged inner surface on each tube formed. The superconducting electrons travel in the cylindrical space between the inside of the nanotubes and the outside of the carbon strings. Cables carrying 5,000 amperes of electric current and withstanding 81,300 pound pull are projected. Strings connect to super-dense diamond plates at the two ends of a cable which plates both carry electric current and carry the pulling force.

This patent application is a continuation in part of application Ser. No. 10/983,380: SUPERCONDUCTING CARBON 12 STRINGS AND METHODS OF MANUFACTURE OF CABLES CONTAINING PARALLEL STRINGS filed on Nov. 8, 2004.

### BACKGROUND OF THE INVENTION

The electric utility industry is currently using superconductors which require expensive cryogenic cooling.

An overall look at efficiencies of electric power systems in the United States leads to estimates that 10 to 20 percent of prime mover input energy is consumed in electrical losses before it is received by users of electric energy. At 10 cents per kilowatt hour this computes to as much as $50 to $100 billion per year that could possibly be saved by use of loss-less superconductors that require no cryogenic cooling.

Even more savings will result from the use of loss-less superconductors in end use devices. Use of cables of this invention in cities of the future could eliminate the present interconnected electric power network of generation, transmission and distribution of electric energy. Use of energy per person in such cities may be reduced by a factor of 1000.

### SUMMARY OF THE INVENTION

A super-dense form of a carbon diamond is described as a cubic form of carbon in which the magnetic directions of the atomic core, acting as bar magnets, are reversed in checkerboard fashion over layers of the diamond. Magnetic force lines circulate between reversed pairs of carbon atoms pulling them together with considerable force in a first method of forming hardness of the diamond. The layers of the super-dense diamond are further arranged with magnetic fields attracting pairs of atoms end to end in a second way that bar magnets can attract each other.

In this form the carbon atoms have collapsed to a state where their valence electron paths touch. A magnetic field of 8.13 pounds force is produced between the nuclei of the atoms forming a super-dense diamond having a cubic lattice of carbon atoms.

Extreme temperatures and pressures applied to a conventional carbon diamond are required to form a super-dense carbon diamond. Alternatively super-dense diamonds can be formed using molecular beam epitaxy (MBE) deposition technology.

A mono layered single dimensional super-dense carbon diamond forms a superconducing string with magnetic directions of atoms alternating 180° along the string. One electron per atom is left over in the single dimensional string for carrying superconducting electric currents.

Single superconducting strings of carbon atoms carry approximately one half ampere of current and will support 8.13 pounds of pull. It is estimated that ribbon cables with 10,000 parallel strands could carry 5,000 amperes of electric current and hold tensional loads of up to 81,300 pounds.

Both single strings and 100×100 stacks of 10,000 parallel strings are smaller than can be seen using ordinary light.

These loosely bonded electrons flow between the exterior of the strings and the inside surface of a special plastic used to form nanotubes around each string in a multi-string cable. The special teflon like plastic forms negatively charged surfaces along the inside of the nanotubes effectively repelling the superconducting electrons to a cylindrical pathway between the plastic tube and the atomic string.

Cables have ribbons of superconducting carbon strings terminated by super-dense carbon diamond plates at both ends. These plates allow superconducting currents to flow in either direction over the ribbons of carbon strings. The plates can also be used as pulling attachments for mechanical loads.

### BRIEF DESCRIPTIONS OF THE DRAWINGS

FIG. 1a A view in the plane of touching valence electrons of six carbon atoms with alternating magnetic directions.

FIG. 1b A view of the carbon atoms of FIG. 1a rotated 90° so as to show electron flow in two directions releasing one electron from each atom for forming superconductivity.

FIG. 2a A view of 10 carbon atoms forming a superconductive string contained in a plastic nanotube.

FIG. 2b A cross section of the carbon superconducting string in a plastic nanotube.

FIG. 3 A diagram of a super-dense carbon diamond.

FIG. 4 A super-dense carbon diamond terminating plate for superconducting carbon strings, each in a plastic nanotube.

### DETAILED DESCRIPTION OF THE PREFERRED EMBODIMENT

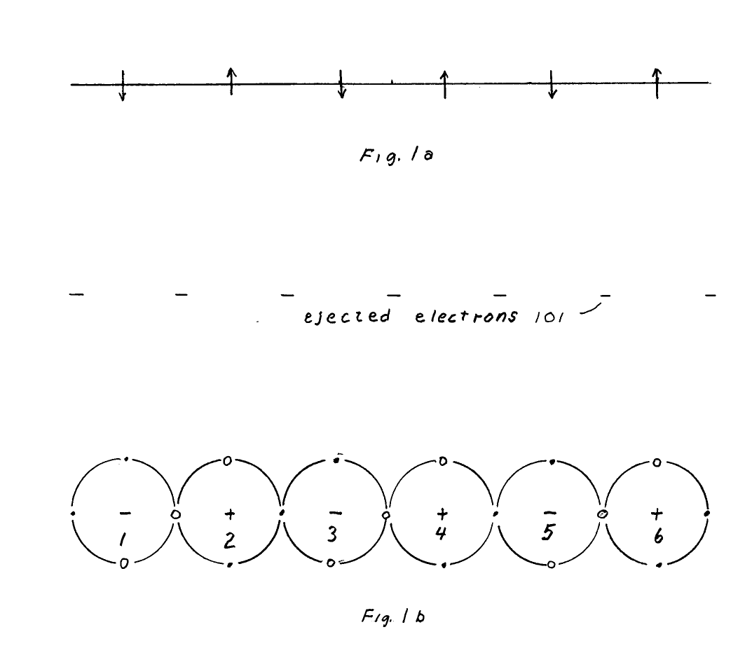

FIGS. 1a and 1b show six atoms, numbered 1 through 6, of a superconducting string of carbon atoms. The atoms have their magnetic direction alternating along the string. Moreover the atoms are in a super-dense relation with their outer four valence electrons touching each other at a midpoint between each pair of atoms along the string. Since two electrons cannot be at this midpoint at the same time, one electron per atom is ejected from the string and is useable for superconductivity.

FIG. 1a shows the carbon atoms in the plane of the valance electrons. Up and down arrows show the alternating magnetic direction of the atoms.

FIG. 1b shows the carbon atoms at right angles to the view of FIG. 1a. The four valence electrons of carbon no longer flow around individual atoms but rather flow in a forward FIG. 8 wave pattern from right to left and back as backward reversed wave pattern from left to right. The electron required at the midpoint is alternatively furnished by the forward and then the backward electron currents. The forward current is shown with electrons represented by circles and the backward current with electrons represented as dots. As can be seen, the electron at the midpoint is furnished by the forward current during the rising portion of its wave. The electron at the midpoint is furnished by the backward current during the falling portion of its wave.

The magnetic force required by the nucleus of an atom such as carbon to hold its four outer valence atoms in orbit as shown in FIGS. 1a and 1b is derived as follows:
1. The force acting on a moving charge is given by: F_{B}=qv×B where B is the magnetic field force vector.

The force symbol B is measured in Teslas.

One Tesla is defined as one Newton/(coulomb meter/second)

Since an Ampere is defined as one coulomb/second, therefore
2. 1 Tesla=1 Newton/Ampere meter

For a circulating charge, q, moving at right angles to a uniform magnetic field, the relationship is:
3. r=mv/qB

solving for B, the magnetic field yields:
4. B=mv/qr

For an electron orbiting a nucleus at an average radius of half the atomic diameter, the values would be:
5. B=(9.09×10⁻³¹ kg) (3×10⁸ meter/second)/((1.6×10⁻¹⁹ Coulomb) (0.5×10⁻¹⁰ meters)=3.41×10⁷ Tesla

This is the magnetic field necessary to constrain electrons to their orbit.

The force equal to the magnetic field of equation 5 is found from:
6. F=qv×B

F=(1.6×10⁻¹⁹ Coul.) (3×10⁸ m/s) (3.41×10⁷ T.)

F=1.637×10⁻³ Newtons

since 4.45 Newtons equals approximately one pound:

F=3.68×10⁻⁴ pounds

Note that this is the force that the valence electrons exert on the nucleus.
7. C12 has 12 neutrons and protons in the nucleus thus has a mass of 12.

The difference in mass of a neutron or proton and an electron is approximately 1840.

The magnetic field of the nucleus that attracts electrons and holds them in orbit, is therefore:

F=(3.68×10⁻⁴)×12×1840

F=8.13 pounds

Note that these forces have a direction but, like a rubber band, have no beginning or end. This then is the force between two atomic cores, acting as bar magnets, located side by side with magnetic fields alternating in direction in a first of two stable orientations of two closely bonded atoms. The same force holds two atoms together with their fields joined head to tail in the second of two stable orientations of two closely bonded atomic cores, acting as bar magnets.

The current that can be carried by a superconducting carbon string is calculated as follows:

Assuming that the superconducting electrons flow at the speed of light along the outside of the carbon string, one can derive the current flow along a single string 81:
1. The diameter of a carbon atom is approximately 1×10⁻¹⁰ meters.
2. The speed of light is 3×10⁸ meters/second.
3. The transit time across each C12 atom is distance/velocity=1×10⁻¹⁰/3×10⁸ meters per second=3.33×10⁻¹⁹ seconds.
4. The number of electrons passing any point along string 81=1/3.33×10⁻¹⁹=3×10¹⁸
5. One Ampere=1 coulomb/second.
6. One Coulomb=6.24×10¹⁸ electrons.
7. The maximum current along a single string 81 is therefore:

6.24×10¹⁸/3×10¹⁸=0.52 Amperes.

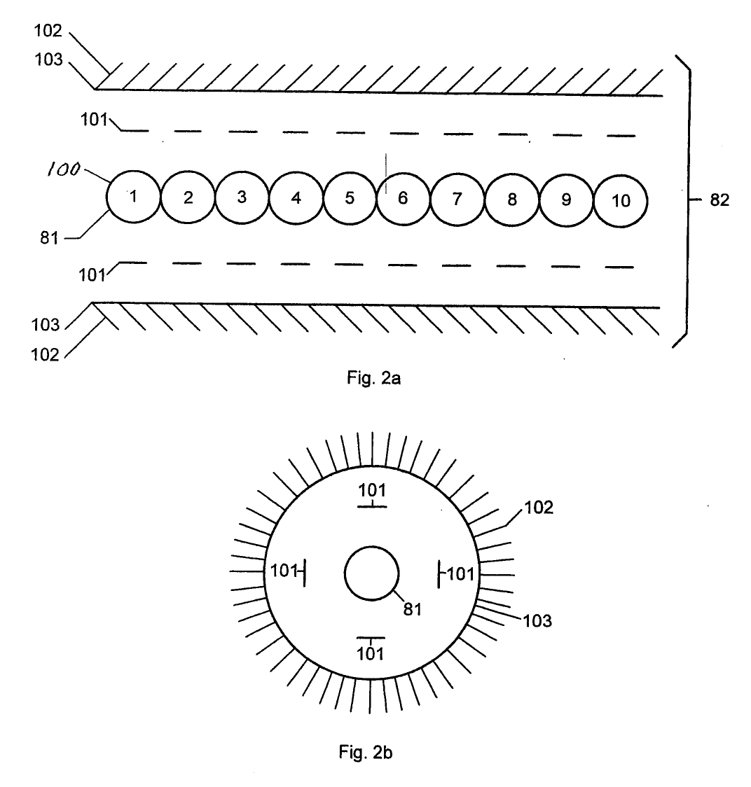

FIGS. 2a and 2b show a superconducting nanotube 82. FIG. 2a shows a superconducting string 81 of 10 carbon atom valence electron circular paths numbered 1 through 10. Said forward and backward valence electrons flowing in circular paths 100 flow as described under FIG. 1b. Said superconducting electrons 101 first shown under FIG. 1b are shown flowing in the space in FIGS. 2a and 2b between string 81 and a special teflon-like plastic tube 102. It is the nature of said special teflon-like plastic to have a layer 103 of electrons on its surface. Said electron flow 100 on the surface of string 81 together with said electron charged surface 103 repel said superconducting electrons 101 to a midpoint between the nanotube surface 103 and string 81. Note that superconductive currents can flow in either direction of nanotubes 82, but not in both directions at the same time.

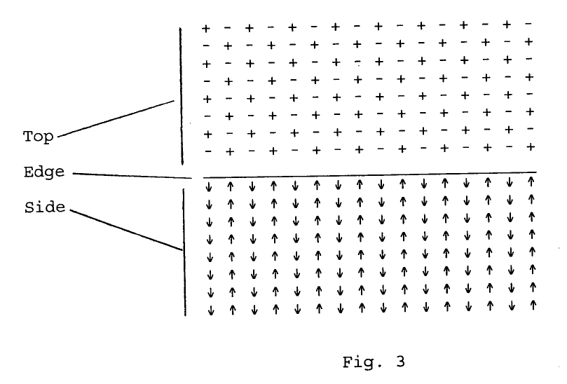

FIG. 3 shows the top of a super-dense carbon 12 diamond having a lattice of alternating tops (+) and bottoms (−) of the magnetic fields of the carbon atoms shown for the top layer of the diamond. The area shown is 16 atoms across and 8 atoms front to back. With the neighboring pairs of magnetic fields reversed the atoms attract each other in the first of two modes magnets may attract each other.

If forward and backward valence electrons were shown flowing in the top layer of FIG. 3, as explained in more detail under FIG. 1b above, that electrons would weave FIG. 8 patterns both from front to back and from side to side of the top layer.

Unlike electron paths in single carbon atoms, when in the dense diamond form the electrons follow paths perpendicular to the directions of the magnetic fields shown as in FIG. 1b. These paths overlap with the magnetic fields holding all electrons in planes parallel to the top. The forces make 180° turns at the ends of each row across or front to back of the top of the diamond.

Down the side, one sees the magnetic forces of carbon atoms going down from top to bottom and returning in adjacent paths from bottom to top. Each two such paths reverse direction and return at the top and bottom thus completing a “rubber band” of magnetic force lines.

The edge defines the 90° break between the top and the side of the C12 diamond. Arrows in the first row below the edge show the alternating magnetic fields of the atoms of each horizontal layer of the diamond. Horizontal atomic layers of the diamond are identical to each other. Each layer shows that the magnetic fields of the atoms attract each other end to end in the second of the two ways that magnetic fields of atoms stably attract each other.

One can conceptually duplicate the structure of closely bonded C12 diamonds using a number of bar shaped permanent magnets. Such magnets will attract each other sideways when to magnetic polarities are reversed and also attract each other end to end with polarities all in the same direction. Two planes of such magnets can be made in 4×4 patterns of 16 magnets each. When four such planes are placed one above the other, a very strong cube structure results conceptually duplicating the super-dense form of carbon diamonds.

It is necessary to terminate said superconducting string 81 on both ends with super-dense carbon diamonds capable of sending and receiving said forward and backward electron currents 100. Currents termed forward at one terminating end are considered backward at the other terminating end. The top of FIG. 3 shows rows of carbon atoms with magnetic atomic polarity alternating from pointing up (+) and down (−). Atomic layers identical to the top layer are stacked one above the other with atomic polarity all pointing up (↑) in one column or all pointing down (↓) in alternate columns.

Valence electron bands touch as in FIGS. 1a and 1b but in three dimensions. There are no electron repulsion between atoms in the super-dense carbon diamond adding to the magnetic coupling between adjacent and atoms giving hardness 10,000 times that of ordinary carbon diamonds. Moreover superconducting electrons abound within the super-dense diamond capable of carrying superconductive currents in any direction.

It is necessary to terminate superconductive strings with super-dense carbon terminating plates. The following discussion estimates that 10,000 strings can be spaced across a one centimeter terminating plate.

The diameter of the path of four outer electrons in carbon atoms is 10⁻¹⁰ meters. Considering one centimeter a practical width of a terminating plate, there are 10⁸=100 million atoms across a one centimeter super-dense carbon diamond. If a superconductive ribbon had 10,000 carbon strings side by side they can be spaced every 10⁴=every 10,000 atoms across a one centimeter terminator. The ribbon cable is brought out from a single layer of a super-dense carbon diamond plate. With 500 layers of super-dense carbon diamond added on either side of the layer connected to superconducting strings a one millimeter thickness plate results.

It is necessary for said teflon like plastic nanotubes 82 to touch the surface of the terminator plate. The distance of 10,000 atoms between superconducting strings is adequate for this requirement.

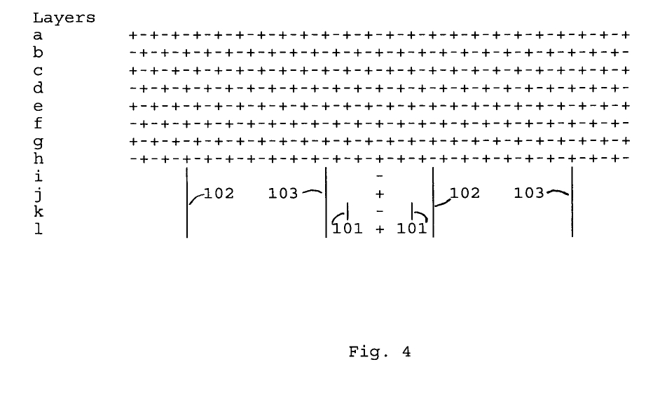

FIG. 4 shows a portion of a super-dense carbon terminator having 8 atomic height, layers a through h. A carbon superconductor string 5 atoms long marked i through m extends down from the terminator with a pattern of magnetic orientation with (+) indicating up and (−) indicating down. In this way the said forward and backward valence electron flow will be provided by the terminator plate. FIG. 4 further shows said plastic nanotube 102 with electron coated inside surface 103 for containing said superconducting electrons 101.

A cable, constructed as described herein, can be vibrated longitudinally as a means of sending information. The stiffness of the cable indicates messages can be sent by modulation of longitudinal vibrations using various well known methods of encoding information into such vibrations.

The following article is taken from a publication by “The New Mexico Facetor” summarizing a speech by Dr. Ralph Dawson:

“Program Speaker: Dr. Ralph Dawson, Crystal Grower.

By Drs. Scott and Susan Wilson

Dr. Ralph Dawson, who recently retired from Sandia National Laboratories as a crystal grower, spoke to the Guild about basic crystal classes and their unique crystal lattice arrangements. For thirty years, Dr. Dawson grew crystals using a technique known as molecular beam epitaxy (MBE). Molecular beam epitaxy allows the crystal grower to precisely grow very thin layers of atoms (known as mono-layers) with controlled thickness. This technique permits highly advanced semiconductors structures to be grown, such a Vertical Cavity emitting Lasers (VCELs).

The materials that Dr. Dawson works with are mainly III-V compounds. These are binary (2 component) chemical compounds formed from one element taken from the 3rd column of the periodic table, along with one element taken from the 5th column of the periodic table. Hence, the name “three-five compounds”.

Examples of these types of compounds are Gallium-Arsenide (GaAs) and Indium-phosphide (InP). These compounds are of great interest in the manufacturing of semiconductor lasers (your CD player has one). In his introduction, Dr. Dawson described the three degrees of crystallization that a solid material may take: amorphous, polycrystalline, and a single crystal. The differences between these three types are based upon the size of an ordered region within the material.

An ordered region is a volume within where the atoms (or molecules) exhibit regular geometric or periodic arrangements. Amorphous material, such as glass, has order only on a length scale of a few atoms (very, very small).

In both cases above, the ordered regions vary in size and orientation with respect to each other (rotated or displaced). Single crystal material, mainly what we faceters work with, has a high degree of order over a long range (several millimeters).

A single crystal region is called a grain. Adjacent crystal grains are separated by grain boundaries. These grain boundaries effect how well a material conducts electricity, and they may also influence the strength of the material.

The periodic arrangement of the atoms in the single crystal is called the “lattice”. The 3D lattice is a periodic repetition of atoms. Since the lattice structure has repetitions within, there must be a group of atoms. Since the lattice structure has repetition within, there must be some fundamental unit being repeated across the whole lattice. This fundamental unit is called the unit cell. By stacking unit cells above, below, and next to each other, we can build the full lattice structure to fill any given volume in the crystal.

There are seven crystal systems: triclinic, monoclinic, orthorhombic, tetragonal, cubic, hexagonal, and trigonal. fourteen possible unit cells exist and are known collectively as the Bravis lattices. Two things need to be kept in mind: which crystal system and which unit cell structure.

Dr. Dawson explained the symmetry found in as crystal. Since the crystal is formed with repeating unit cells, it logically follows that there will be some symmetry in the arrangement of the crystal lattice.

The crystal symmetry can be seen by rotating models of the different crystal lattice structures. for example, if the crystal structure is cubic, then the lattice will look like a box with an atom at each corner of the box. If we hold the box to look only at the front of the box, then we only see four atoms (one at each corner). If we rotate the box to look at one of the other sides, it will appear exactly the same to us. There is no visible difference in the four sides. This is an example of four-fold symmetry.

To satisfy interests of the group, Dr. Dawson spoke about cleavage planes in material. Crystals will cleave (break apart along crystal planes) where the atomic bonds are weakest. Bond strength is a function of the distance between adjacent atoms. The closer the atoms are to each other, the stronger the bond. Dr Dawson mentioned that one must take into account the density of the bonds on adjacent layers. For example, on a given crystal plane, the bond strength between the atoms on either side of the plane may be weak. However, many atoms may be connected together across the plane and prevent the crystal from cleaving along that plane. Those bonds may be weak, but there are a lot of them.

There is one crystal lattice arrangement that Dr. Dawson identified as THE most technologically important for mankind: the diamond structure. Clearly the diamond structure is that exhibited by diamonds, with the lattice points being carbon atoms. Other materials may crystallize in the diamond structure, and among them is the element silicon. Silicon is used extensively in the semiconductor industry to make all of the integrated circuits and transistors that run our computers, cars, phones, and our lives.”

### ADVANTAGES OF THE INVENTION

1. Superconducting strings for carrying electric currents without the need for cryogenic cooling will eliminate voltage drops and power losses in electric power transmission and distribution lines.

2. Superconducting strings for carrying electric currents without the need for cryogenic cooling will eliminate power losses in electric power generators and transformers.

3. At http://www.metropolismag.com/html/content_{—}0203/fib/ Peter Testa Architects describe buildings of the future which use no concrete or steel but rather use plastics and ceramics to suggest buildings that are very strong but also very light as compared to present technology.

It is interesting to assume the success of the present invention and the future use of cables of say 10,000 parallel strands of carbon strings. This could be equivalent to a square bundle of 100×100 strings. These bundles would be 10⁻⁸ meters square in size, still too small to see with ordinary light. If 10,000 strings, each in a plastic nanotube, are spread across a one centimeter ribbon cable the cable would carry 5,000 amperes of current from building to building. The cables would also have a strength of 8.13 lbs per strand multiplied by 10,000 strands for a pull strength of 81,300 pounds! Such cables could supply bracing for the buildings and support catwalks between buildings at levels above street level. At the same time electric power can be distributed among the buildings over the cables. Some cables might carry 3 Vdc for computers. Other cables might carry 24 Vdc for lighting, air conditioning, etc.

If the carbon string technology is applied to end use devices further changes may be contemplated. The power efficiencies of end use devices can be improved greatly reducing the energy required per person using the buildings.

While the invention has been particularly shown and described with reference to preferred embodiments thereof, it will be understood by those skilled in the art that various changes in form and details may be made therein without departing from the spirit and scope of the invention.

What I claim is:

1. An assembly of atomic strings comprising in combination:
a) carbon atom means for forming strings,
b) string construction means for forming strings with the core magnetic directions of said atoms alternating from up to down,
c) string construction means for placing said carbon atoms with their valence electron orbits touching each other at midpoints between atoms along said strings thus ejecting an electron from each midpoint,
d) super-dense carbon diamond termination plate means for terminating both ends of multiple said strings,
e) carbon string to super-dense carbon diamond termination plate connection means for providing valence electron flows in both directions between ends of said carbon strings, and
f) crossing said valence electron flows at said midpoints between atoms whereby the electrons at said midpoints between atoms are alternately furnished by one and then the other of the valence electron current flows.

2. An assembly of atomic strings as in claim 1 with said string construction means using molecular beam epitaxy technology.

3. An assembly of atomic strings as in claim 1 further comprising in combination:
a) plastic means for holding said multiple strings in parallel ribbons, and
b) surface means for said plastic for forming negatively charged nanotubes around each said multiple string permitting said ejected electrons to flow between terminating plates as superconducting currents in the spaces between said strings and said nanotubes.

4. An assembly of atomic strings as in claim 3 further comprising in combination a second plastic means for placing an outer protective cover over said multiple strings in parallel ribbons between terminating plates thus forming a superconductive cable.

5. Superconductive cables as in claim 4 further comprising vibrational communications means for communicating via longitudinal vibrations along said cable.

6. An assembly of atomic strings as in claim 1 further comprising in combination:
a) said plate termination means for connecting multiple said strings to one layer of super-dense carbon diamond for producing valence electron flow in both directions between ends of said carbon strings, and
b) additional layers of super-dense carbon diamond means for adding above and below said one layer of super-dense carbon diamond thus forming a termination plate of useful thickness.

7. A method of producing wide temperature range superconducting cables, said method comprising the steps of:
a) forming strings of carbon atoms having alternating directions of atomic magnetic force along said string,
b) forming said strings with valence electron paths of carbon atoms touching at midpoints between each pair of atoms along said string thus ejecting one electron from each midpoint,
c) forming super-dense carbon diamond terminating plates at both ends of multiple strings for furnishing valence electron flows in either direction between said terminating plates,
d) forming nanotubes of special plastic around each multiple string having electron surfaces on insides of said nanotubes, and
e) terminating said nanotubes at terminating plates for permitting said ejected electrons to flow as superconductive current in either direction between said terminating plates.
